(19) United States
(12) Patent Application Publication
(10) Pub. No.: US 2010/0209623 A1
(43) Pub. Date: Aug. 19, 2010

(54) APPARATUS FOR GROWING LARGE AREA VANADIUM DIOXIDE THIN FILM AND METHOD OF GROWING LARGE AREA OXIDE THIN FILM IN THE APPARATUS

(75) Inventors: Bong Jun Kim, Daejeon-City (KR); Giwan Seo, Incheon-City (KR); Hyun Tak Kim, Daejeon-City (KR)

Correspondence Address: RABIN & Berdo, PC, 1101 14TH STREET, NW, SUITE 500, WASHINGTON, DC, 20005, US

(73) Assignee: ELECTRONICS AND TELECOMMUNICATIONS RESEARCH INSTITUTE, Daejeon-City (KR)

(21) Appl. No.: 12/687,185

(22) Filed: Jan. 14, 2010

(30) Foreign Application Priority Data
Feb. 18, 2009 (KR) 10-2009-0013507
Oct. 7, 2009 (KR) 10-2009-0095129

(51) Int. Cl. C23C 16/46; C23C 16/00; C23C 16/06

(52) U.S. Cl. 427/576; 118/723 R; 118/725

(57) ABSTRACT

Provided is a technology for in-situ growing a large area VO₂ thin film which is an MIT material without using a conductive adhesive for high temperatures such as a silver paste. Generally, when a VO₂ thin film, which is an MIT material, is grown using a PLD or sputtering method under a high temperature, a conductive adhesive is used to improve thermal conduction. However, the thin film may be contaminated by the conductive adhesive and the conductive adhesive should be removed after growing the thin film. Therefore, adherence between the substrate and the surface of a heater when growing the thin film needs to be improved, and thus, a large area VO₂ thin film growing apparatus which may grow the large area VO₂ thin film easily and a method of growing the large area VO₂ thin film are provided.

### CROSS-REFERENCE TO RELATED PATENT APPLICATION

This application claims the benefit of Korean Patent Application Nos. 10-2009-0013507, filed on Feb. 18, 2009 and 10-2009-0095129, filed on Oct. 7, 2009, in the Korean Intellectual Property Office, the disclosure of which is incorporated herein in its entirety by reference.

### BACKGROUND OF THE INVENTION

1. Field of the Invention

The present invention relates to an apparatus and method of growing a large area oxide thin film, and in particular, to an apparatus and method of in-situ growing a large area thin film having a uniform thin film property.

2. Description of the Related Art

When a thin film is in-situ grown by a thin film deposition apparatus such as by a sputter deposition, a pulsed laser deposition (PLD), or a chemical vapor deposition (CVD), an appropriate growth temperature is determined by heat supplied from a heater on which a substrate is placed. Halogen lamp heaters or molding heaters are mainly used in the growth of thin films, and may use heat by radiation or conduction from a heating material at a high temperature. A substrate may be fixed on the heater in various ways, for example, the substrate may be directly placed on the heater or the substrate may be fixed on a holder that is placed on the heater.

In order to in-situ grow vanadium dioxide (VO₂), which is a metal-insulator-transition (MIT) material, a contact between the substrate and the heater is very important, that is, it is impossible to grow VO₂ when the substrate is simply placed on the heater or on the holder. Therefore, the substrate is directly attached to the heater by using a silver paste, which functions as a conductive adhesive for high temperatures, in order to improve a thermal conductivity between the substrate and the heater, and then, a VO₂ thin film is grown. If the conductive adhesive for high temperatures is not used, a VOx phase having little MIT properties is formed. Therefore, the thermal conductive property caused by a contact between the substrate and the heater, that is, the heat source, is more important than any other growth conditions in growing the VO₂ thin film, which is the MIT material.

Conventionally, a method of combining an MIT material, which is not an in-situ growing method, has been suggested as a technology of growing a VO₂ thin film. According to the conventional method, a material that may have MIT properties is deposited in a substrate in advance, and after that, the material having the MIT properties is formed through a post thermal treatment under appropriate conditions.

### SUMMARY OF THE INVENTION

The present invention provides an apparatus for in-situ growing a large area vanadium oxide (VO₂) thin film that has metal-insulator-transition (MIT) properties at a high temperature without using a conductive adhesive, and a method of growing a large area oxide thin film in the apparatus.

According to an aspect of the present invention, there is provided an apparatus for growing a large area vanadium dioxide (VO₂) thin film, the apparatus including: a target comprising a deposition material; a large area substrate facing the target; a heater disposed under the substrate to heat the substrate; and a fixing device for mechanically fixing the large area substrate to the heater without using an adhesive.

The heater may include on an upper surface of the heater a material which does not thermally deform. The material which does not thermally deform may have a polished surface and is adhered on an upper surface of a body portion in the heater. The fixing device may have a ring-shaped structure which may cover an outer portion of the substrate to fix the substrate on the heater. The fixing device may be coupled to an outer portion on the upper surface of the heater, on which the substrate is not disposed, via screws.

A large area oxide thin film of one selected from the group consisting of YBaCuO, LaSrMnO, LaCaMnO, SrTiO, BaTiO, TiOx, WOx, and NiOx may be deposited and grown in the apparatus.

According to another aspect of the present invention, there is provided a method of growing a large area oxide thin film on a substrate by using the thin film growing apparatus.

The large area oxide thin film may be in-situ grown on the substrate. The oxide may be a vanadium dioxide (VO₂). The oxide may be an oxide selected from the group consisting of YBaCuO, LaSrMnO, LaCaMnO, SrTiO, BaTiO, TiOx, WOx, and NiOx.

### BRIEF DESCRIPTION OF THE DRAWINGS

The above and other features and advantages of the present invention will become more apparent by describing in detail exemplary embodiments thereof with reference to the attached drawings in which:

FIG. 1 is a perspective view of an apparatus for growing a large area VO₂ thin film therein, according to an embodiment of the present invention;

FIG. 2 is an exploded perspective view of the apparatus for growing the large area VO₂ thin film of FIG. 1;

FIG. 3 is a cross-sectional view of the large area VO₂ growing apparatus of FIG. 2, in which a fixing device is fixed to a heater;

FIG. 4 is an exploded view of a large area VO₂ thin film growing apparatus according to another embodiment of the present invention;

FIG. 5 is a cross-sectional view of the large area VO₂ thin film growing apparatus of FIG. 4, in which a fixing device is fixed to the heater;

FIG. 6 is an exploded view of a large area VO₂ thin film growing apparatus according to another embodiment of the present invention;

FIG. 7 is a detailed perspective view of the large area VO₂ thin film growing apparatus of FIG. 6, in which the fixing device is fixed to the heater;

FIG. 8 is a scanning electron microscope (SEM) photograph of a VO₂ thin film grown under a temperature of 700° C. by the large area VO₂ thin film growing apparatus of FIG. 2 according to the embodiment of the present invention;

FIG. 9A is a conceptual diagram showing positions of measuring a thickness of a two-inch VO₂ thin film which is grown by the large area VO₂ thin film growing apparatus of FIG. 2 according to the embodiment of the present invention;

FIG. 9B shows SEM cross-section photographs taken at the positions shown in FIG. 9A; and

FIG. 10 is a graph of the resistance of the VO₂ thin film, which is grown by the large area VO₂ thin film growing apparatus of FIG. 2 according to the embodiment of the present invention, with respect to temperature.

### DETAILED DESCRIPTION OF THE INVENTION

The present invention will now be described more fully with reference to the accompanying drawings, in which exemplary embodiments of the invention are shown.

A first method of growing VO₂, which is a metal-insulator-transition (MIT) material, includes two stages, that is, a VOx oxide material, which is close to V₂O₅, is grown in an appropriate temperature, and after that, a VO₂ phase is formed by a secondary thermal treatment. In the secondary thermal treatment, a substrate is attached to a heater by using a conductive adhesive for high temperatures to grow the VO₂ phase at a high temperature. A second method of growing VO₂ is a method of in-situ growing VO₂ at a high temperature after directly attaching a substrate onto a heater by using a conductive adhesive for high temperatures. However, according to the two methods above, the conductive adhesive for high temperatures must be used, a thin film may be contaminated at a high temperature, and the substrate may not be evenly attached to the heater when a large area substrate is used. In order to address these problems, the present invention provides an apparatus for in-situ growing a large area VO₂ thin film which has a uniform thin film property by using a molding heater instead of the conductive adhesive, and a method of growing a large area oxide thin film in the apparatus.

The present invention will now be described more fully with reference to the accompanying drawings, in which exemplary embodiments of the invention are shown. It will also be understood that when a layer is referred to as being “on” another layer or substrate, it can be directly on the other layer or substrate, or intervening layers may also be present. Like reference numerals in the drawings denote like elements, and thus their description will be omitted. In the drawings, the thicknesses of layers and regions are exaggerated for clarity. The invention may, however, be embodied in many different forms and should not be construed as being limited to the embodiments set forth herein; rather, these embodiments are provided so that this disclosure will be thorough and complete, and will fully convey the concept of the invention to those of ordinary skill in the art.

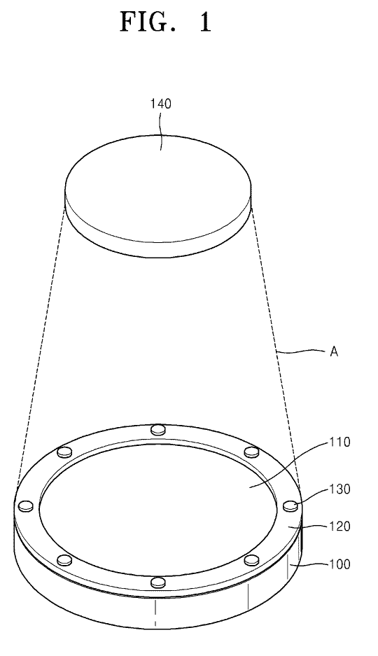

FIG. 1 is a perspective view of an apparatus for growing a large area VO₂ thin film therein, according to an embodiment of the present invention.

Referring to FIG. 1, the large area VO₂ growing apparatus of the present embodiment includes a heater 100, a substrate 110, a fixing device 120, and a target 140 which are disposed in a chamber (not shown).

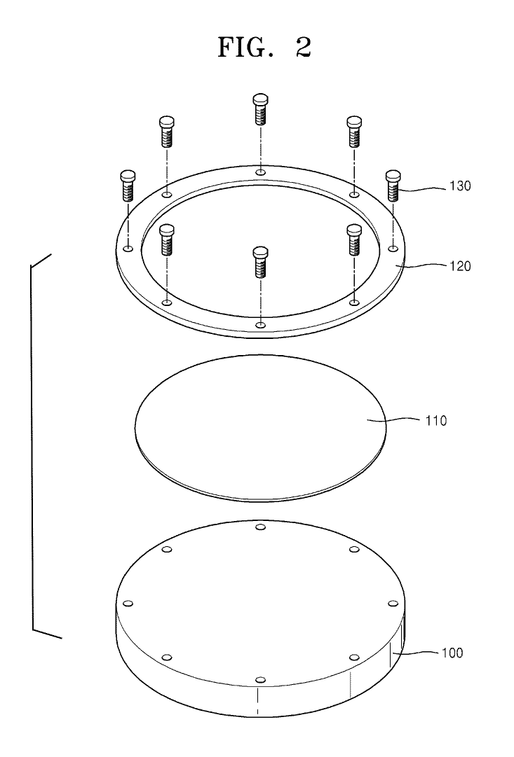

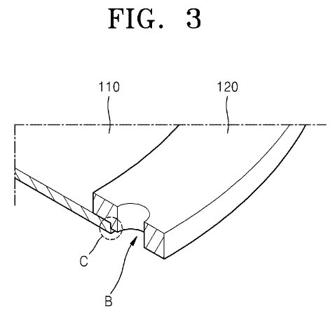

According to the large area VO₂ growing apparatus of the present embodiment, the substrate 110 is fixed on the heater 100 without using a conductive adhesive for high temperatures, for example, a silver paste. That is, the fixing device 120 is fixed to the heater 100 via fixing screws 130 in the large area VO₂ growing apparatus of the present embodiment, and thereby fixing the substrate 110 onto the heater 100. The large area VO₂ growing apparatus of the present embodiment will be described in more detail with reference to FIGS. 2 and 3.

The fixing device 120 is formed to have a ring structure, which is adhered to an outer portion of the substrate 110 to be coupled to the heater 100 via the fixing screw 130, and thus, the substrate 110 may be mechanically fixed to the heater 100 without using the conductive adhesive. On the other hand, in the large area VO₂ growing apparatus having the structure in which the substrate 110 is fixed on the heater 100 without using the conductive adhesive for high temperatures, a vanadium plasma A which is generated from the target 140 formed of a deposition material is deposited on the substrate 110 that is rotated while maintaining the high temperature by the heater 100, and then, a VO₂ thin film is in-situ grown on the substrate 110.

Here, the substrate 110 may be formed of a material which is not deformed at a high temperature, for example, alumina, and may have a large area, for example, two inches or greater, in order to grow a large area VO₂ thin film. In addition, the heater 100 may be formed of a material which does not thermally deform. For example, the heater 100 may be formed of a material such as a quartz, sapphire, or alumina. However, the present invention is not limited to these examples.

The large area VO₂ growing apparatus according to the present embodiment may in-situ grow the VO₂ thin film which is an MIT material without using the conductive adhesive for high temperatures, and accordingly, the number of processes may be reduced and a large area VO₂ thin film having a uniform thin film property may be fabricated easily.

FIG. 2 is an exploded view of the large area VO₂ thin film growing apparatus of FIG. 1.

Referring to FIG. 2, the large area VO₂ growing apparatus of the present embodiment includes the heater 100, the substrate 110, and the fixing device 120 for fixing the substrate 110 on the heater 100.

The fixing device 120 has a ring-shaped structure, an outer circumference of which has a diameter which is greater than that of the substrate 110 and an inner circumference of which has a diameter which is smaller than that of the substrate 110, so that an outer portion of the substrate 110 may be fixed. In addition, the fixing device 120 may have an equal size to that of the heater 100, or greater. That is, the diameter of the outer circumference in the fixing device 120 may be the same as a diameter of the heater 100 or greater.

On the other hand, since the fixing device 120 is coupled to the heater 100 via the fixing screw 130, the fixing device 120 includes screw holes and the heater 100 also includes corresponding screw recesses. The screw holes and the screw recesses may be formed at the closest positions to the substrate as long as the screw holes and the screw recesses do not contact the substrate 110 when the substrate 110 is disposed on the heater 100. In addition, an engaging recess C (see FIG. 3) is formed in an inner lower portion of the fixing device 120 so that a side surface of the substrate 110 may be engaged with the fixing device 120 when the substrate 110 is coupled to the heater 100.

FIG. 3 is a cross-sectional view of the large area VO₂ growing apparatus of FIG. 2, in which the fixing device 120 is fixed to the heater 100.

Referring to FIG. 3, the ring-shaped fixing device 120 is coupled onto the substrate 110, and the engaging recess C is formed in the inner lower portion of the fixing device 120 so that the side surface of the substrate 110 may be placed and fixed therein. Here, a depth of the engaging recess C is less than a thickness of the substrate 110 so that the substrate 110 may be firmly fixed therein. Here, reference letter B denotes a screw hole in which the screw 130 is inserted. The screw hole B may include a female screw. However, the screw recess formed in the heater 100 should include the female screw.

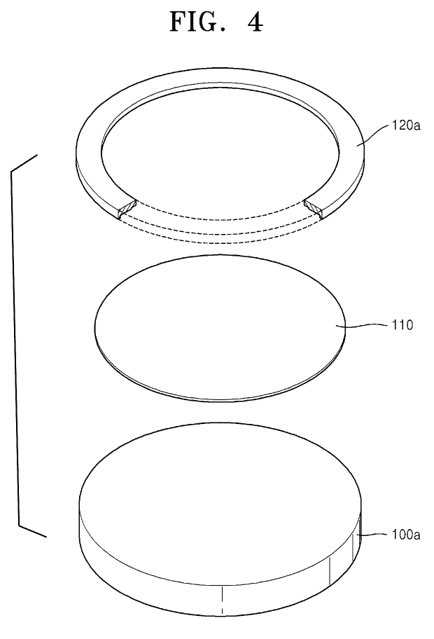

FIG. 4 is an exploded view of a large area VO₂ thin film growing apparatus according to another embodiment of the present invention.

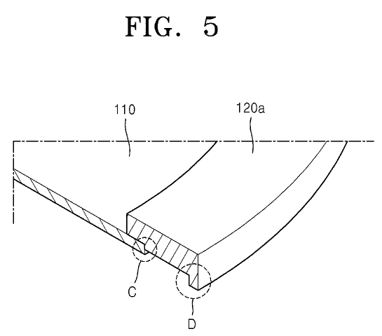

Referring to FIG. 4, the large area VO₂ thin film growing apparatus of the present embodiment is similar to the large area VO₂ thin film growing apparatus of FIG. 2 except for a fixing device 120a, which fixes the substrate 110. That is, the fixing device 120 is not coupled to a heater 100a via screws, but is formed to surround the heater 100a. Accordingly, a diameter of an outer circumference of the fixing device 120a is greater than that of the heater 100a, and a guide wall may be formed in an outer lower surface of the fixing device 120a so as to cover the heater 100a. Structures of the fixing device 120a will be described in more detail with reference to FIG. 5.

On the other hand, since the fixing device 120a does not use screws, the fixing device 120a and the heater 100a do not include screw holes and screw recesses.

FIG. 5 is a cross-sectional view of the large area VO₂ thin film growing apparatus of FIG. 4, in which the fixing device 120a is fixed to the heater 100a (the heater 100a is not shown in FIG. 5).

Referring to FIG. 5, the fixing device 120a includes the engaging recess C in an inner lower portion thereof, as described with reference to FIG. 3. A guide wall D which may surround the heater 100a is formed in an outer lower surface of the fixing device 120. A height of the guide wall D should be greater than the thickness of the substrate 110 because the fixing device 120a covers the heater 100a while pressing against the substrate 110.

On the other hand, the fixing device 120a should be fixed on the heater 100a even when the heater 100a rotates in growing oxide thin films. Accordingly, the fixing device 120a includes a slight protrusion (not shown) on the guide wall D so that the protrusion may be coupled to a recess (not shown), which is formed in an outer side surface of the heater 100a in advance, like a snap fastener, or the fixing device 120a may be coupled to the heater 100a while the fixing device 120a presses against the substrate 110 due to the weight of the fixing device 120a.

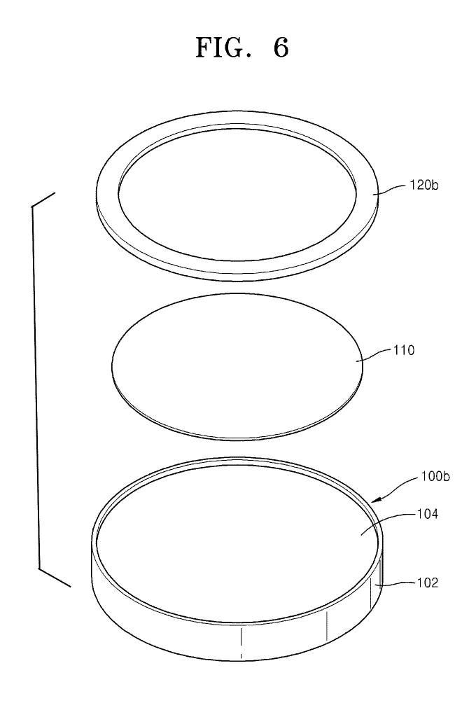

FIG. 6 is an exploded view of the large area VO₂ thin film growing apparatus according to another embodiment of the present invention.

Referring to FIG. 6, the large area VO₂ thin film growing apparatus of the present embodiment includes a heater 100b, the substrate 110, and a fixing device 120b like the large area VO₂ thin film growing apparatus shown in FIG. 2 or FIG. 4; however, the structures of the heater 100b and the fixing device 120b are different from those of FIG. 2 or FIG. 4.

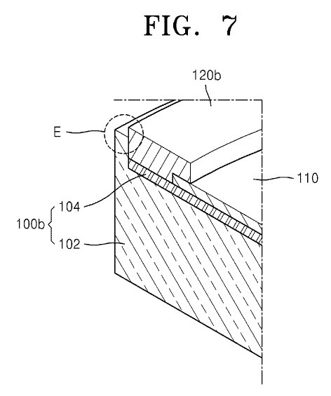

The fixing 120b is formed to be able to be received in the heater 100b, and accordingly, a diameter of the outer circumference of the fixing device 120b is smaller than a diameter of the heater 100b. In addition, a guide wall E (see FIG. 7) is formed in an outer portion of the heater 100b so that the fixing device 120b is received in the heater 100b. The fixing device 120b having the above-described structure does not use screws, and thus, the fixing device 120b and the heater 100b do not include screw holes and screw recesses. Structures of the fixing device 120b and the heater 100b will be described with reference to FIG. 7.

On the other hand, unlike the previous embodiments, the heater 100b includes on an upper surface thereof a thin film 104 formed of a material different from that of the heater 100b, that is, the thin film 104 formed of a material which does not thermally deform. Therefore, the heater 100b of the present embodiment includes a body portion 102 on which the guide wall E is formed and the thin film 104 which is formed of the material that does not thermally deform and is surrounded by the guide wall E on the upper surface of the body portion 102. The thin film 104 is formed of the material, a surface of which is polished, that does not thermally deform at a high temperature, that is, may be formed of quartz, sapphire, or alumina. However, the present invention is not limited thereto, that is, the thin film 104 may be formed of other materials which do not thermally deform at a high temperature.

As described above, since the thin film 104 formed of the material which does not thermally deform is permanently fixed on the upper surface of the heater 100b, contamination on surfaces of the heater 100b or deformation of the heater 100b may be prevented. The structure in which the thin film 104 formed of the material which does not thermally deform is formed on the upper surface of the body portion 102 of the heater 100b, and the substrate 110 is fixed on the thin film 104 via the fixing device 120b, as illustrated in FIG. 7 in more detail.

On the other hand, the thin film 104 is not formed on the upper surface of the heater 100 shown in FIG. 2 or FIG. 4; however, the thin film 104 may be formed on the upper surface of the heater 100 to prevent the surface of the heater 100 from being contaminated or being deformed.

FIG. 7 is a detailed perspective view of the large area VO₂ thin film growing apparatus of FIG. 6, in which the fixing device 120b is fixed to the heater 100b.

Referring to FIG. 7, the heater 100b includes the body portion 102 and the thin film 104 formed of the material which does not thermally deform. The guide wall E is formed in an outer portion of the body portion 102 in order to receive and fix the fixing device 120b.

The fixing device 120b includes an engaging recess like the other fixing devices 120 and 120a in the previous embodiments so as to fix the substrate 110 therein by engaging with the substrate 110. In addition, a diameter of the outer circumference of the fixing device 120b is nearly the same as that of the thin film 104 formed on the upper surface of the body portion 102 of the heater 100b. For example, the diameter of the outer circumference of the fixing device 120b may be equal to an inner diameter of the guide wall E so that the fixing device 120b is received in the guide wall E of the body portion 102.

On the other hand, a small protrusion (not shown) may be formed on the guide wall E so as to be coupled to a recess (not shown) which is formed in an outer side surface of the fixing device 120b in advance, like a snap fastener. Otherwise, the fixing device 120b may be coupled to the heater 100b while the fixing device 120b presses against the substrate 110 due to the weight of the fixing device 120b. The fixing device 120b coupled to the heater 100b as described above does not move even when the heater 100b rotates when growing oxide thin films.

The growing of the large area VO₂ thin film in the large area VO₂ thin film growing apparatus is described below; however, other large area oxide thin films, for example, YBaCuO, LaSrMnO, LaCaMnO, SrTiO, BaTiO, TiOx, WOx, and NiOx thin films may be deposited and grown in the large area VO₂ thin film growing apparatus of the present invention.

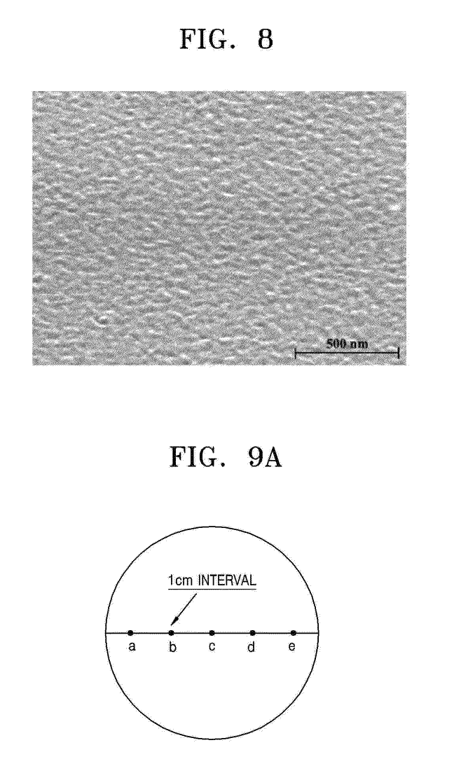

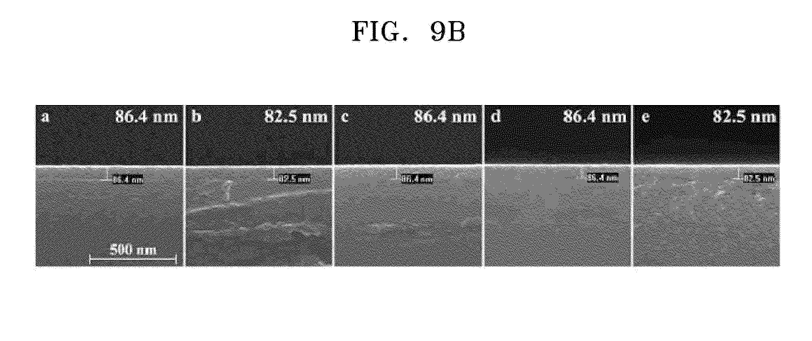

A VO₂ thin film is grown on an alumina substrate of two inches using a PLD method under a temperature of 700° C. in the large area VO₂ thin film growing apparatus shown in FIG. 2, and after that, a surface and a thickness of the thin film is observed with a scanning electron microscope (SEM) in order to analyze the characteristics of the VO₂ thin film. The observation results are shown in FIGS. 8 through 9B.

FIG. 8 is a SEM photograph of the VO₂ thin film which was grown at a temperature of 700° C. by using the large area VO₂ thin film growing apparatus of FIG. 2 according to the present embodiment.

FIG. 8 shows the SEM photograph of the surface of the VO₂ thin film grown in the apparatus of FIG. 2, where crystallized grains may have sizes of tens to hundreds of nanometers. That is, the VO₂ thin film grown by the large area VO₂ thin film growing apparatus of the present embodiment has grains of relatively uniform sizes.

FIG. 9A is a conceptual diagram showing positions at which a thickness of the thin film is measured in the two-inch VO₂ thin film which is grown by the large area VO₂ thin film growing apparatus of FIG. 2 according to the present embodiment.

FIG. 9A shows the positions at which the thickness of the VO₂ thin film is measured on the substrate of two-inch thickness, and at which the SEM photographs of the cross-section of the VO₂ thin film are taken at intervals of 1 cm, as shown in FIG. 9B.

FIG. 9B shows the SEM cross-section photographs taken at the positions of FIG. 9A.

Referring to FIG. 9B, the thickness of the VO₂ thin film is constant at each of the positions. That is, even if there is a slight error, the thicknesses of the VO₂ thin film measured at the intervals of 1 cm are 86 nm on average.

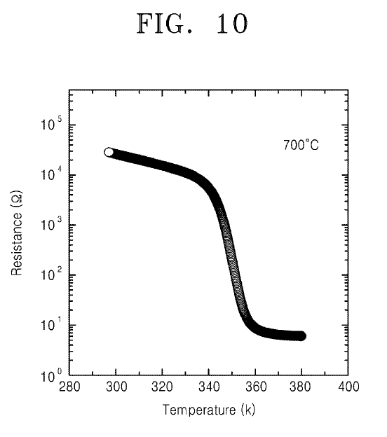

FIG. 10 is a graph showing the resistance of a VO₂ thin film, which is grown by the large area VO₂ thin film growing apparatus of FIG. 2, with respect to temperature. The x-axis denotes the temperature in Kelvins, and the Y-axis denotes the resistance in ohms.

Referring to FIG. 10, from the resistance versus temperature graph, the VO₂ thin film grown by the large area VO₂ thin film growing apparatus of the present embodiment has MIT properties. That is, according to the resistance versus temperature graph, the large area VO₂ thin film shows MIT properties around a temperature of 340K, and has a resistance transference width of about 10³ order.

According to a large area VO₂ thin film growing apparatus and method of the present invention, a VO₂ thin film which is formed of an MIT material is in-situ grown without using a conductive adhesive for high temperatures, such as a silver paste, and accordingly, the number of processes may be reduced and a large area VO₂ thin film which is uniform may be fabricated easily.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. An apparatus for growing a large area vanadium dioxide (VO₂) thin film, the apparatus comprising:
a target comprising a deposition material;
a large area substrate facing the target;
a heater disposed under the substrate to heat the substrate; and
a fixing device for mechanically fixing the large area substrate to the heater without using an adhesive.

2. The apparatus of claim 1, wherein the heater comprises on an upper surface of the heater a material which does not thermally deform.

3. The apparatus of claim 2, wherein the material which does not thermally deform has a polished surface and is adhered on an upper surface of a body portion in the heater.

4. The apparatus of claim 1, wherein the body portion of the heater comprises a material which does not thermally deform.

5. The apparatus of claim 2, wherein the material which does not thermally deform comprises quartz, sapphire, or alumina.

6. The apparatus of claim 1, wherein the fixing device has a ring-shaped structure which may cover an outer portion of the substrate to fix the substrate on the heater.

7. The apparatus of claim 6, wherein the fixing device comprises an engaging recess in an inner surface thereof for placing a side surface of the substrate, and a depth of the engaging recess is less than a thickness of the substrate.

8. The apparatus of claim 7, wherein the upper surface of the heater is larger than the substrate, the substrate is disposed on a center portion of the upper surface of the heater, and the fixing device is coupled to an outer portion on the upper surface of the heater, on which the substrate is not disposed, via screws.

9. The apparatus of claim 7, wherein the upper surface of the heater is larger than the substrate, the substrate is disposed on a center portion of the upper surface of the heater, and the fixing device is coupled to the heater through a guide wall which is formed in an outer portion of the fixing device to surround the heater.

10. The apparatus of claim 7, wherein the heater includes a guide wall in an outer upper portion to receive the substrate and the fixing device.

11. The apparatus of claim 10, wherein the upper surface of the heater surrounded by the guide wall is larger than the substrate, the substrate is disposed on a center portion of the upper surface of the heater, and the fixing device includes an engaging recess in an inner side surface for fixedly placing a side surface of the substrater on the engaging recess.

12. The apparatus of claim 11, wherein an outer side surface of the fixing device contacts an inner side surface of the guide wall, and the fixing device is fixed onto the heater via a protrusion formed on the inner side surface of the guide wall or via the weight of the fixing device.

13. The apparatus of claim 10, wherein the heater comprises a surface-polished material, which does not thermally deform, and the material is attached on a surface of a portion surrounded by the guide wall.

14. The apparatus of claim 1, wherein a large area oxide thin film of one selected from the group consisting of YBaCuO, LaSrMnO, LaCaMnO, SrTiO, BaTiO, TiOx, WOx, and NiOx is deposited and grown in the apparatus.

15. The apparatus of claim 1, wherein the substrate is a large area substrate having a diameter of two inches or greater.

16. A method of growing a large area oxide thin film on a substrate by using the thin film growing apparatus of claim 1.

17. The method of claim 16, wherein the large area oxide thin film is in-situ grown on the substrate.

18. The method of claim 16, wherein the oxide is a vanadium dioxide (VO₂).

19. The method of claim 16, wherein the oxide is an oxide selected from the group consisting of YBaCuO, LaSrMnO, LaCaMnO, SrTiO, BaTiO, TiOx, WOx, and NiOx.

20. The method of claim 16, wherein the heater of the thin film growing apparatus includes a surface-polished material which does not thermally deform on an upper surface of the heater in order to prevent the upper surface of the heater from being contaminated or deformed when growing the large area oxide thin film.
